(19) United States
(12) Patent Application Publication
(10) Pub. No.: US 2009/0109068 A1
(43) Pub. Date: Apr. 30, 2009

(54) Touch control input device, and computer apparatus including the same

(76) Inventors: Chih-Hsien Yeh, Taipei City (TW); Chih-Ching Hu, Taipei City (TW); Jeremy Casey Liu, Taipei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/289,351

(22) Filed: Oct. 27, 2008

Related U.S. Application Data
(60) Provisional application No. 61/000,905, filed on Oct. 30, 2007.
(60) Provisional application No. 61/001,065, filed on Oct. 31, 2007.

(51) Int. Cl. H03K 17/94; G06F 3/041

(52) U.S. Cl. 341/34; 345/173

(57) ABSTRACT

A touch control input device includes a flexible dielectric touch plate disposed above a dielectric substrate. A conducting unit includes first conductive membrane patterns formed on a top surface of the substrate and spaced apart from each other, and second conductive membrane patterns formed on a bottom surface of the touch plate and corresponding respectively to the first conductive membrane patterns. A spacer is disposed between the substrate and the touch plate for spacing each first conductive membrane pattern apart from the corresponding second conductive membrane pattern. Pressing of the touch plate so that at least one first conductive membrane pattern electrically contacts the corresponding second conductive membrane pattern results in outputting of an input signal by the conducting unit. One of the substrate and the touch plate is formed with a predetermined pattern that is visible from above the touch plate.

### CROSS-REFERENCE TO RELATED APPLICATION

This application claims priority of U.S. Provisional Applications No. 61/000905 filed on Oct. 30, 2007 and No. 61/001065 filed on Oct. 31, 2007.

### BACKGROUND OF THE INVENTION

1. Field of the Invention

The invention relates to an input device, more particularly to a touch control input device.

2. Description of the Related Art

FIG. 1 illustrates a conventional resistive touchpad 100 that includes a glass substrate 110 coated with a conductive membrane, and a conductive film 120 disposed on the glass substrate 110 and spaced apart from the conductive membrane by a spacer (not shown). Two first conductive wirings 140 are formed on opposite sides of the conductive film 120, and are opposite to each other in an X direction. Two second conductive wirings 130 are formed on opposite sides of the glass substrate 110, and are opposite to each other in a Y direction. The conventional resistive touchpad 100 is operable to generate an input signal by contacting a touch pen or one finger of a user with the conductive film 120 in order to enable the conductive film 120 to touch the conductive membrane on the glass substrate 110. The input signal corresponds to activity of an object located at a touch point on the conventional resistive touchpad 100, and is processed to generate an X-direction signal and a Y-direction signal corresponding to the input signal.

However, the conventional resistive touchpad 100 cannot serve as a keyboard for a computer apparatus. In addition, the conventional resistive touchpad 100 is not configured to perform an input operation corresponding to simultaneous pressing of multiple touch points.

### SUMMARY OF THE INVENTION

Therefore, an object of the present invention is to provide a touch control input device, and a computer apparatus including the same that can overcome the aforesaid drawback of the prior art.

According to one aspect of the present invention, a touch control input device comprises:

a dielectric substrate having top and bottom surfaces;

a flexible dielectric touch plate disposed on the top surface of the dielectric substrate, and having top and bottom surfaces;

a conducting unit including
a plurality of first conductive membrane patterns formed on the top surface of the dielectric substrate and spaced apart from each other, and
a plurality of second conductive membrane patterns formed on the bottom surface of the dielectric touch plate and corresponding respectively to the first conductive membrane patterns; and

a spacer disposed between the dielectric substrate and the dielectric touch plate for spacing each of the first conductive membrane patterns on the dielectric substrate apart from the corresponding one of the second conductive membrane patterns on the dielectric touch plate.

Pressing of the dielectric touch, plate so that at least one of the first conductive membrane patterns electrically contacts the corresponding one of the second conductive membrane patterns results in outputting of an input signal by the conducting unit.

One of the dielectric substrate and the dielectric touch plate is formed with a predetermined pattern that is visible from above the dielectric touch plate.

According to another aspect of the present invention, a computer apparatus comprises:

a touch control input device including
a dielectric substrate having top and bottom surfaces,
a flexible dielectric touchplate disposed on the top surface of the substrate, and having top and bottom surfaces,
a conducting unit including
   a plurality of first conductive membrane patterns formed on the top surface of the dielectric substrate and spaced apart from each other, and
   a plurality of second conductive membrane pattern formed on the bottom surface of the dielectric touch plate and corresponding respectively to the first conductive membrane patterns, and
a spacer disposed between the dielectric substrate and the dielectric touch plate for spacing each of the first conductive membrane patterns on the dielectric substrate apart from the corresponding one of the second conductive membrane patterns on the dielectric touch plate,

wherein pressing of the dielectric touch plate so that at least one of the first conductive membrane is patterns electrically contacts the corresponding one of the second conductive membrane patterns results in outputting of an input signal by the conducting unit, and

wherein one of the dielectric substrate and the dielectric touch plate is formed with a predetermined pattern that is visible from above the dielectric touch plate;

a display unit; and

a processing unit coupled to the display unit and the conducting unit of the touch control input device, receiving the input signal from the conducting unit of the touch control input device, and generating an output corresponding to the input signal received thereby and displayed on the display unit.

### BRIEF DESCRIPTION OF THE DRAWINGS

Other features and advantages of the present invention will become apparent in the following detailed description of the preferred embodiments with reference to the accompanying drawings, of which:

FIG. 1 is an exploded perspective view showing a conventional touchpad;

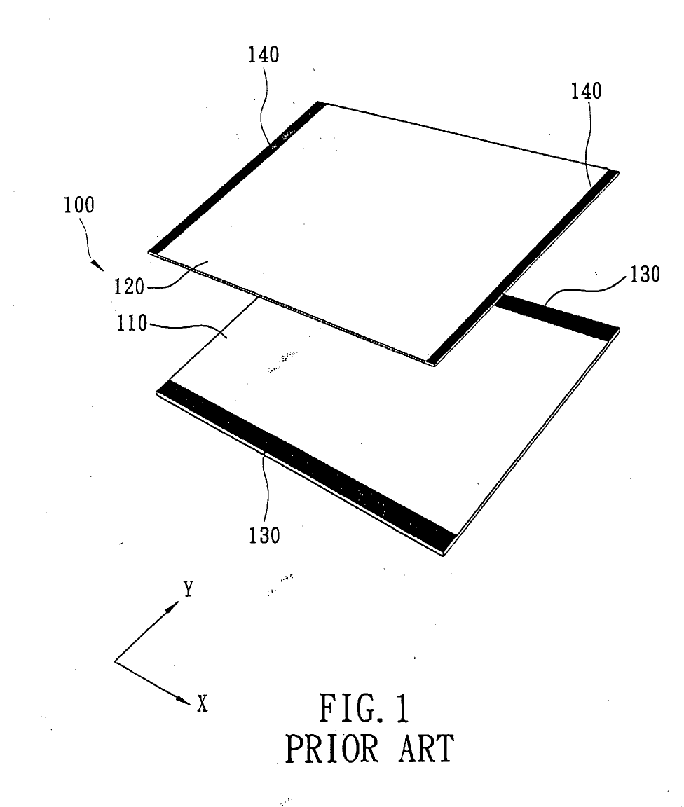

FIG. 2 is a partly exploded perspective view showing the first preferred embodiment of a touch control input device according to the present invention;

FIG. 3 is a partly exploded, fragmentary perspective view showing an input module of the first preferred embodiment;

FIG. 4 is a schematic side view showing the first preferred embodiment;

FIG. 5 is a fragmentary schematic side view showing the input module of the first preferred embodiment when in a non-operated state;

FIG. 6 is a fragmentary schematic side view showing the input module of the first preferred embodiment when in an operated state;

FIG. 7 is a schematic side view showing the second preferred embodiment of a touch control input device according to the preferred embodiment; and

FIG. 8 is a perspective view of a computer apparatus including the touch control input device of the second preferred embodiment.

### DETAILED DESCRIPTION OF THE PREFERRED EMBODIMENTS

Before the present invention is described in greater detail, it should be noted that like elements are denoted by the same reference numerals throughout the disclosure.

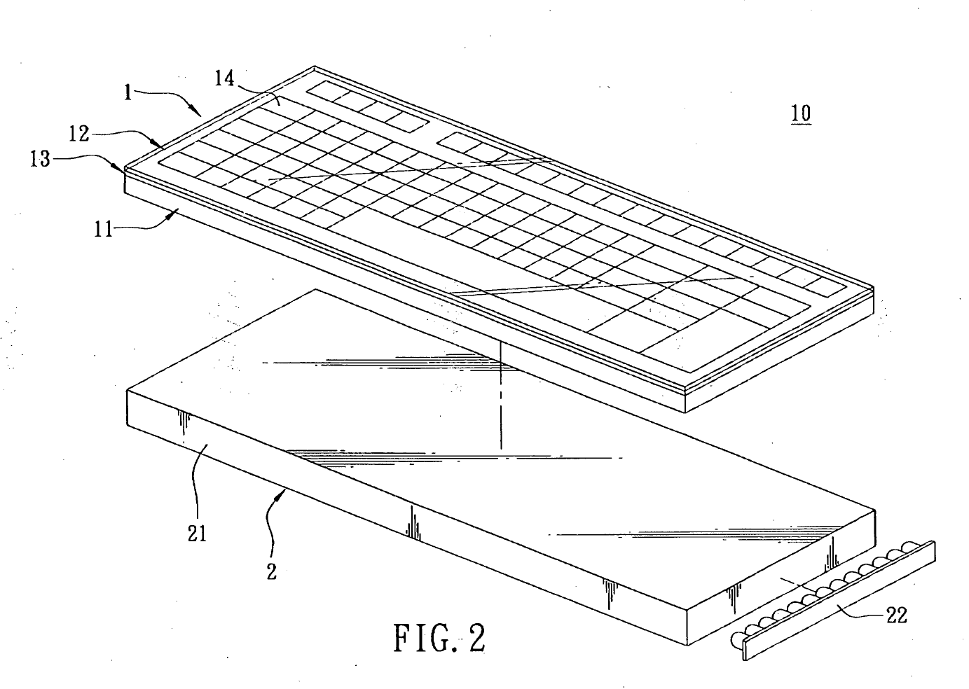

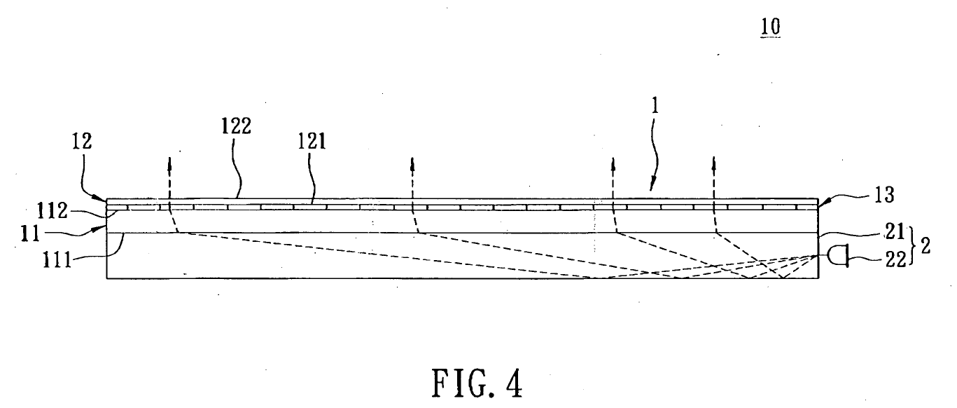

Referring to FIGS. 2 and 4, the first preferred embodiment of a touch control input device 10 according to the present invention is shown to include an input module 1 and a lighting unit 2. In this embodiment, the touch control input device 10 can serve as a keyboard for a computer apparatus.

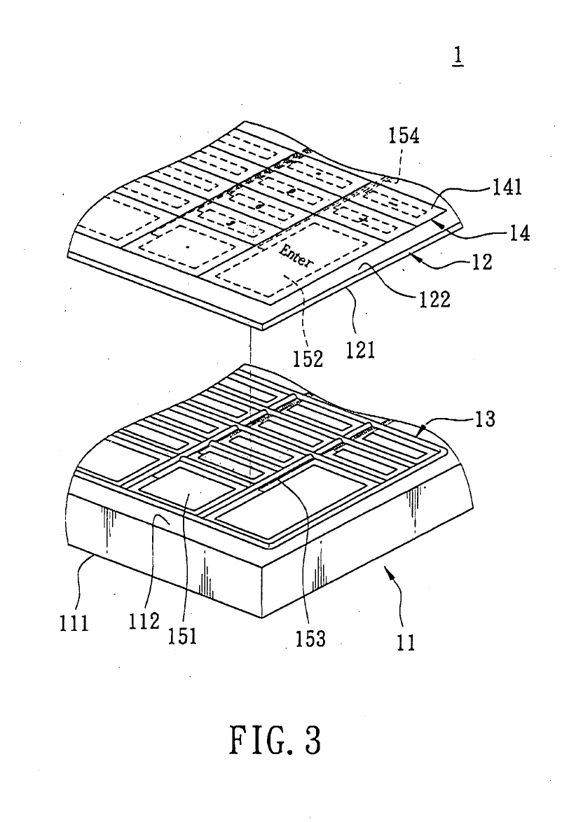

Referring further to FIG. 3, the input module 1 includes a dielectric substrate 11, a flexible dielectric touch plate 12, a conducting unit, and a spacer 13.

The substrate 11 has top and bottom surfaces 112, 111. In this embodiment, the substrate 11 is transparent, and is made of glass.

The touch plate 12 is transparent in this embodiment, is disposed on the top surface 112 of the substrate 11, and has top and bottom, surface 122, 121. In this embodiment, the touch plate 12 is made of polyethylene terephthalate (PET) or acrylic plastic.

The conducting unit includes a plurality of first conductive membrane patterns 151 formed on the top surface 112 of the substrate 11 and spaced apart from each other, a plurality of second conductive membrane patterns 152 formed on the bottom surface 121 of the touch plate 12 and corresponding respectively to the first conductive membrane patterns 151, a plurality of first conductive wirings 153 formed on the top surface 112 of the substrate 11 and connected electrically and respectively to the first conductive membrane patterns 151, and a plurality of second conductive wirings 154 formed on the bottom surface 121 of the touch plate 12 and connected electrically and respectively to the second conductive membrane patterns 152, as shown in FIG. 3. In this embodiment, the first and second conductive membrane patterns 151, 152, and the first and second conductive wirings 153, 154 are transparent, and are made of indium tin oxide (ITO).

The spacer 13 is disposed between the substrate 11 and the touch plate 12 for spacing each of the first conductive membrane patterns 151 on the substrate 11 apart from the corresponding one of the second conductive membrane pattern 152 on the touch plate 12, as shown in FIG. 3.

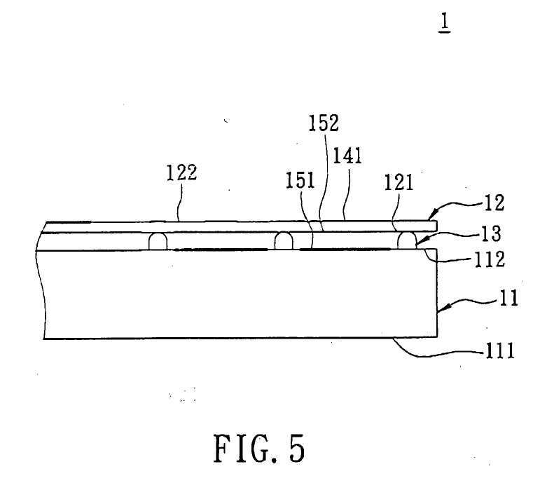

In this embodiment, the top surface 122 of the touch plate 12 is formed with a predetermined pattern 14 by printing or engraving. In other embodiments, the predetermined pattern 14 can be formed on the bottom surface 111 of the substrate 11, and is visible from above the touch plate 12 due to the transparent characteristics of the substrate 11, the touch plate 12 and the conductive membrane patterns 151, 152 of the conducting unit. Furthermore, in this embodiment, the predetermined pattern 14 is in the form of a keyboard pattern that includes a plurality of character pattern portion 141 corresponding respectively to the second conductive membrane patterns 152 on the touch plate 12, as shown in FIG. 5.

The lighting unit 2 is disposed under the substrate 11 for radiating light toward the substrate 11. In this embodiment, as shown in FIG. 4, the lighting unit 2 serves as a backlight module, and includes a light guide plate 21 mounted on the bottom surface 111 of the substrate 11, and a light source 22 for radiating light toward the light guide plate 21. The light radiated from the light source 22 is guided by the light guide plate 21 toward the substrate 11. In other embodiments, the lighting unit 2 can be a cold light emitting planar source.

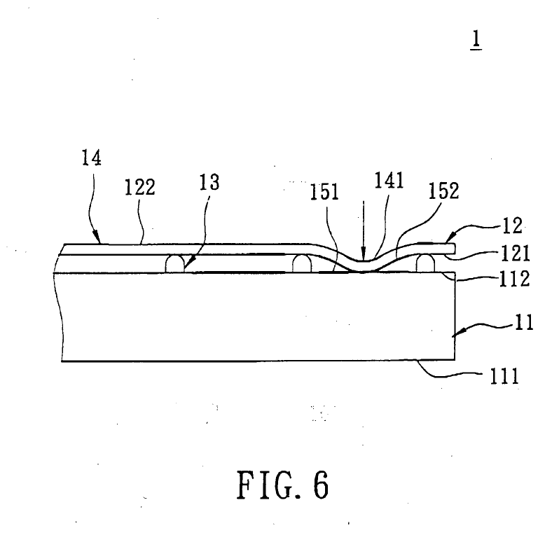

Pressing of the touch plate 12 so that at least one of the first conductive membrane patterns 151 electrically contacts the corresponding one of the second conductive membrane patterns 152 (see FIG. 6) results in outputting of an input signal by the conducting unit. For example, when a touch point on the touch plate 12 corresponding to one of the character pattern portions 141 of the predetermined pattern 14 that indicates the numeral “3” is pressed, the input signal corresponding to the numeral “3” is outputted by the conducting unit. In another example, when three touch points on the touch plate 12 corresponding to three character pattern portions 141 of the predetermined pattern 14 are pressed simultaneously, the input signal corresponding to a combination of the three character pattern portions 141 is outputted by the conducting unit.

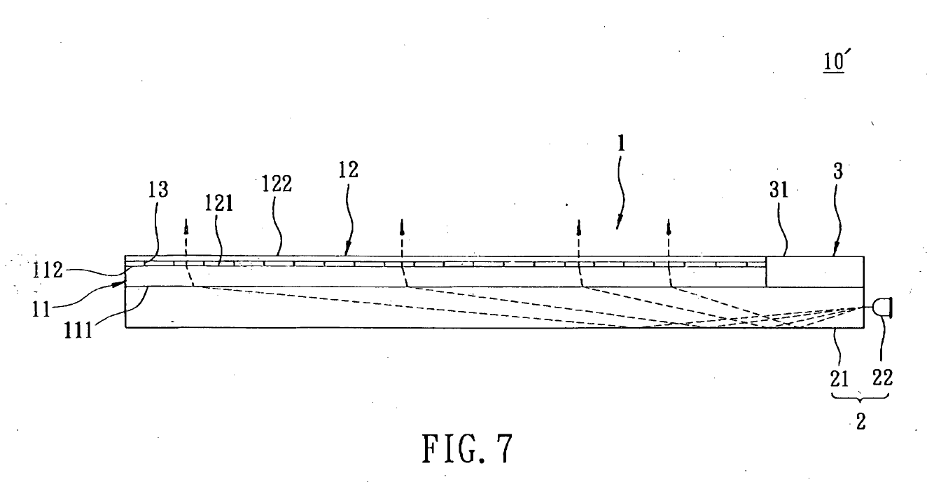

FIG. 7 illustrates the second preferred embodiment of a touch control input device 10′ according to this invention, which is a modification of the first preferred embodiment. Unlike the previous embodiment, the touch control input device 10′ further includes a touchpad 3 disposed on the lighting unit 2, and having a top surface 31 coplanar with the top surface 122 of the touch plate 12. In this embodiment, the touchpad 3 can be a resistive touchpad or a capacitive touchpad.

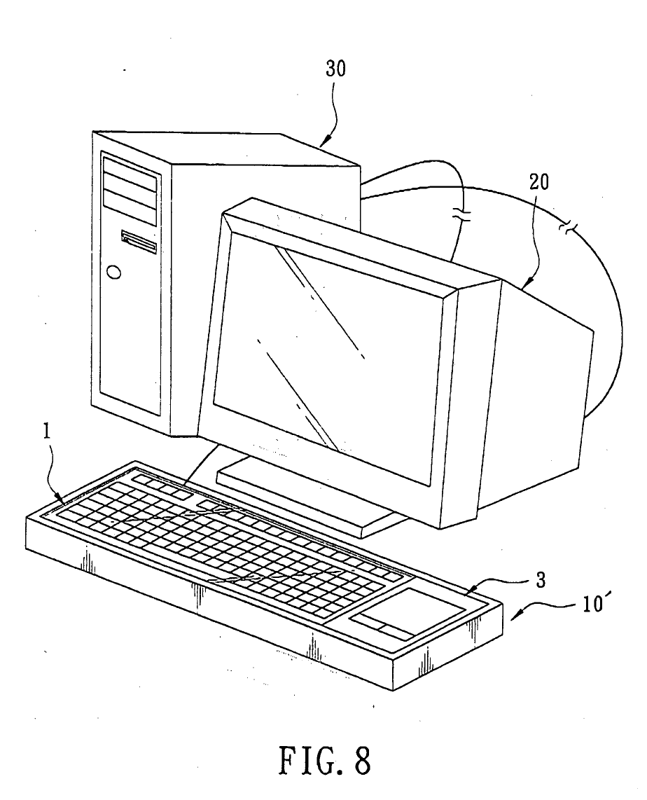

FIG. 8 illustrates a computer apparatus that includes the touch control input device 10′ of the second preferred embodiment, a display unit 20, and a processing unit 30 coupled to the display unit 20 and the touch control input device 10′. The processing unit 30 receives the input signal from the conducting unit of the touch control input device 10′, and generates an output corresponding to the input signal received thereby and displayed on the display unit 20.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

We claim:

1. A touch control input device comprising:
a dielectric substrate having top and bottom surfaces;
a flexible dielectric touch plate disposed on said top surface of said dielectric substrate, and having top and bottom surfaces;
a conducting unit including
a plurality of first conductive membrane patterns formed on said top surface of said dielectric substrate and spaced apart from each other, and
a plurality of second conductive membrane patterns formed on said bottom surface of said dielectric touch plate and corresponding respectively to said first conductive membrane patterns; and
a spacer disposed between said dielectric substrate and said dielectric touch plate for spacing each of said first conductive membrane patterns on said dielectric substrate apart from the corresponding one of said second conductive membrane patterns on said dielectric touch plate;
wherein pressing of said dielectric touch plate so that at least one of said first conductive membrane patterns electrically contacts the corresponding one of said second conductive membrane patterns results in outputting of an input signal by said conducting unit; and
wherein one of said dielectric substrate and said dielectric touch plate is formed with a predetermined pattern that is visible from above said dielectric touch plate.

2. The touch control input device as claimed in claim 1, wherein said conducting unit further includes:
a plurality of first conductive wirings formed on said top surface of said dielectric substrate and connected electrically and respectively to said first conductive membrane patterns; and
a plurality of second conductive wirings formed on said bottom surface of said dielectric touch plate and connected electrically and respectively to said second conductive membrane patterns.

3. The touch control input device as claimed in claim 1, wherein one of said top surface of said dielectric touch plate and said bottom surface of said dielectric substrate is formed with said predetermined pattern.

4. The touch control input device as claimed in claim 3, wherein said predetermined pattern is formed on said one of said top surface of said dielectric touch plate and said bottom surface of said dielectric substrate by printing.

5. The touch control input device as claimed in claim 3, wherein said predetermined pattern is formed on said one of said top surface of said dielectric touch plate and said bottom surface of said dielectric substrate by engraving.

6. The touch control input device as claimed in claim 3, wherein said dielectric substrate, said dielectric touch plate, and said first and second conductive membrane patterns of said conducting unit are transparent.

7. The touch control input device as claimed in claim 6, further comprising a lighting unit disposed under said dielectric substrate for radiating light toward said dielectric substrate.

8. The touch control input device as claimed in claim 7, wherein said lighting unit includes a cold light emitting planar source.

9. The touch control input device as claimed in claim 7, wherein said lighting unit includes a light guide plate mounted on said bottom surface of said dielectric substrate, and a light source for radiating light toward said light guide plate, the light radiated from said light source being guided by said light guide plate toward said dielectric substrate.

10. The touch control input device as claimed in claim 7, further comprising a touchpad disposed on said lighting unit and having a top surface coplanar with said top surface of said dielectric touch plate.

11. The touch control input device as claimed in claim 1, wherein said predetermined pattern is in the form of a keyboard pattern that includes a plurality of character pattern portions corresponding respectively to said second conductive membrane patterns on said dielectric touch plate.

12. A computer apparatus comprising:
a touch control input device including
a dielectric substrate having top and bottom surfaces,
a flexible dielectric touchplate disposed on said top surface of said substrate, and having top and bottom surfaces,
a conducting unit including
a plurality of first conductive membrane patterns formed on said top surface of said dielectric substrate and spaced apart from each other, and
a plurality of second conductive membrane pattern formed on said bottom surface of said dielectric touch plate and corresponding respectively to said first conductive membrane patterns, and
a spacer disposed between said dielectric substrate and said dielectric touch plate for spacing each of said first conductive membrane patterns on said dielectric substrate apart from the corresponding one of said second conductive membrane patterns on said dielectric touch plate,
wherein pressing of said dielectric touch plate so that at least one of said first conductive membrane patterns electrically contacts the corresponding one of said second conductive membrane patterns results in outputting of an input signal by said conducting unit, and
wherein one of said dielectric substrate and said dielectric touch plate is formed with a predetermined pattern that is visible from above said dielectric touch plate;
a display unit; and
a processing unit coupled to said display unit and said conducting unit of said touch control input device, receiving the input signal from said conducting unit of said touch control input device, and generating an output corresponding to the input signal received thereby and displayed on said display unit.
